(19) United States
(12) Patent Application Publication
(10) Pub. No.: US 2025/0344412 A1
(43) Pub. Date: Nov. 6, 2025

(54) HIGH BANDWIDTH MEMORY DEVICES WITH MULTIPLE DECKS

(71) Applicant: Yangtze Memory Technologies Co., Ltd., Wuhan (CN)

(72) Inventors: Hao ZHENG, Wuhan (CN); Dongyu FAN, Wuhan (CN); Tingting GAO, Wuhan (CN); Zhiliang XIA, Wuhan (CN); Zongliang HUO, Wuhan (CN)

(21) Appl. No.: 18/776,178

(22) Filed: Jul. 17, 2024

(30) Foreign Application Priority Data
May 6, 2024 (CN) 202410553471.9

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08146; H01L 2224/80895; H01L 2224/80896; H01L 2225/06513; H01L 2225/06541; H01L 2924/1431; H01L 2924/1436

(57) ABSTRACT

The present disclosure relates to methods, devices, systems, and techniques for managing a high bandwidth memory (HBM) with multiple decks. An example semiconductor device includes multiple decks of semiconductor structures stacked along a first direction, multiple dielectric layers between the multiple decks of semiconductor structures, and multiple groups of contact structures extending along the first direction. The multiple decks of semiconductor structures include at least a first deck of semiconductor structures and a second deck of semiconductor structures. The multiple dielectric layers extend along a second direction perpendicular to the first direction and include at least a first dielectric layer between the first deck of semiconductor structures and the second deck of semiconductor structures. The first deck of semiconductor structures is bonded to the second deck of semiconductor structures by the first dielectric layer.

### CROSS-REFERENCE TO RELATED APPLICATIONS

This application claims priority to Chinese Patent Application No. 202410553471.9, filed on May 6, 2024, which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

A high bandwidth memory (HBM) uses stacked memory devices to enable effective data movement and access. While using less power in a smaller form factor, HBM devices can achieve higher bandwidth. HBM devices have been applied to high-performance graphics accelerators, network devices, high-performance datacenter, artificial intelligence (AI) and machine learning (ML) training, and various supercomputers.

### SUMMARY

The present disclosure describes methods, devices, systems, and techniques for managing high bandwidth memory (HBM) with multiple decks.

One aspect of the present disclosure features a semiconductor device that includes multiple decks of semiconductor structures stacked along a first direction, multiple dielectric layers between the multiple decks of semiconductor structures, and multiple groups of contact structures extending along the first direction. The multiple decks of semiconductor structures include at least a first deck of semiconductor structures and a second deck of semiconductor structures. The multiple dielectric layers extend along a second direction perpendicular to the first direction and include at least a first dielectric layer between the first deck of semiconductor structures and the second deck of semiconductor structures. The first deck of semiconductor structures is bonded to the second deck of semiconductor structures by the first dielectric layer. The multiple groups of contact structures include at least a first group of contact structures and a second group of contact structures. The first group of contact structures are coupled to conductive layers of the first deck of semiconductor structures without extending through the first dielectric layer. The second group of contact structures extend through the first deck of semiconductor structures and the first dielectric layer and are coupled to conductive layers of the second deck of semiconductor structures.

In some implementations, the multiple decks of semiconductor structures further include a third deck of semiconductor structures. The multiple dielectric layers further include a second dielectric layer between the second deck of semiconductor structures and the third deck of semiconductor structures. The multiple groups of contact structures further include a third group of contact structures. The third group of contact structures extend through the first deck of semiconductor structures, the first dielectric layer, the second deck of semiconductor structures, and the second dielectric layer and are coupled to conductive layers of the third deck of semiconductor structures.

In some implementations, the semiconductor device further includes a base die. The multiple decks of semiconductor structures and the base die are stacked along the first direction. The base die is coupled to the first group of contact structures and the second group of contact structures.

In some implementations, the first deck of semiconductor structures is bonded to the base die by a bonding layer between the first deck of semiconductor structures and the base die. The first deck of semiconductor structures includes an interconnect layer in contact with the bonding layer. The bonding layer includes conductive bonding contacts and at least one dielectric material isolating the conductive bonding contacts in the second direction. The base die is coupled to the first group of contact structures and the second group of contact structures by the interconnect layer and the conductive bonding contacts.

In some implementations, the first deck of semiconductor structures is bonded to the base die by conductive micro bumps between the first deck of semiconductor structures and the base die. The first deck of semiconductor structures includes an interconnect layer in contact with the conductive micro bumps. The base die is coupled to the first group of contact structures and the second group of contact structures by the interconnect layer and the conductive micro bumps.

In some implementations, the first deck of semiconductor structures is bonded to the base die by a bonding layer between the first deck of semiconductor structures and the base die. The bonding layer includes at least one dielectric material and excludes a conductive bonding contact. The first group of contact structures and the second group of contact structures extend through the bonding layer and extend into the base die. The base die includes an interconnect layer furthest away from the bonding layer among components in the base die along the first direction. The interconnect layer is coupled to the first group of contact structures and the second group of contact structures.

In some implementations, the multiple dielectric layers further include a first group of dielectric layers between the first deck of semiconductor structures and a second group of dielectric layers between the second deck of semiconductor structures. Two adjacent semiconductor structures of the first deck of semiconductor structures are bonded by one of the first group of dielectric layers. Two adjacent semiconductor structures of the second deck of semiconductor structures are bonded by one of the second group of dielectric layers.

In some implementations, at least one semiconductor structure of the multiple decks of semiconductor structures is a dynamic random-access memory (DRAM) device.

Another aspect of the present disclosure features a semiconductor device including multiple decks of semiconductor structures stacked along a first direction. The multiple decks of semiconductor structures include at least a first deck of semiconductor structures and a second deck of semiconductor structures bonded by a first dielectric layer between the first deck of semiconductor structures and the second deck of semiconductor structures. The semiconductor device further includes a first group of contact structures extending along the first direction and being connected to the first deck of semiconductor structures. The semiconductor device further includes a second group of contact structures extending along the first direction and being connected to the second deck of semiconductor structures. The second group of contact structures include at least a first contact structure. The first contact structure includes a first segment and a second segment. The first segment extends through the first deck of semiconductor structures and the first dielectric layer. The second segment is connected to one of the second deck of semiconductor structures.

In some implementations, the first segment includes a first end and a second end, and the second segment includes a first end and a second end. The first end of the second segment is connected to the second end of the first segment. The first end of the first segment is farther away from the second segment than the second end of the first segment along the first direction. The second end of the second segment is connected to the one of the second deck of semiconductor structures. A size of a cross section of the first end of the second segment is larger than a size of a cross section of the second end of the first segment.

In some implementations, the first end of the second segment is in contact with the first dielectric layer along the first direction. The second end of the first segment is in contact with the first dielectric layer along a second direction perpendicular to the first direction.

In some implementations, each of the first group of contact structures and the second group of contact structures has a critical dimension (CD) in a range between 0.5 micrometers (μm) and 10 μm.

In some implementations, each of the first group of contact structures and the second group of contact structures includes an insulating outer layer and a conductive inner layer surrounded by the insulating outer layer.

In some implementations, at least one semiconductor structure of the multiple decks of semiconductor structures is a DRAM device.

A further aspect of the present disclosure features a method including forming contact holes extending along a first direction in a first deck of semiconductor structures stacked along the first direction. The method further includes stacking a second deck of semiconductor structures on the first deck of semiconductor structures along the first direction. The method further includes forming contact holes extending along the first direction in the second deck of semiconductor structures. The contact holes in the second deck of semiconductor structures include a first group of contact holes and a second group of contact holes. The first group of contact holes extend through the second deck of semiconductor structures and are connected to the contact holes in the first deck of semiconductor structures. The method further includes forming a first group of contact structures and a second group of contact structures. The first group of contact structures are in the contact holes in the first deck of semiconductor structures and the first group of contact holes in the second deck of semiconductor structures. The second group of contact structures are in the second group of contact holes in the second deck of semiconductor structures.

In some implementations, the contact holes in the first deck of semiconductor structures are formed by a first etching process. The contact holes in the first deck of semiconductor structures include at least a first contact hole extending to a conductive layer of a corresponding semiconductor structure in the first deck of semiconductor structures.

In some implementations, the method further includes filling the contact holes in the first deck of semiconductor structures with a sacrificial material and bonding the second deck of semiconductor structures to the first deck of semiconductor structures by a dielectric layer.

In some implementations, the contact holes in the second deck of semiconductor structures are formed by a second etching process. The first group of contact holes in the second deck of semiconductor structures extend through the dielectric layer and extend to the sacrificial material in the contact holes in the first deck of semiconductor structures. The second group of contact holes in the second deck of semiconductor structures include at least a second contact hole extending to a conductive layer of a corresponding semiconductor structure in the second deck of semiconductor structures.

In some implementations, the method further includes removing the sacrificial material in the contact holes in the first deck of semiconductor structures to connect the contact holes in the first deck of semiconductor structures with the first group of contact holes in the second deck of semiconductor structures.

In some implementations, the first group of contact structures are formed by depositing at least one conductive material into the contact holes in the first deck of semiconductor structures and the first group of contact holes in the second deck of semiconductor structures. The second group of contact structures are formed by depositing at least one conductive material into the second group of contact holes in the second deck of semiconductor structures.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a block diagram of an example system having one or more semiconductor devices, according to some aspects of the present disclosure.

FIGS. 2A-2C illustrate example semiconductor devices, according to some aspects of the present disclosure.

FIGS. 3A-3B illustrate example semiconductor devices that each include the semiconductor device of FIG. 2A and a computing device, according to some aspects of the present disclosure.

FIGS. 4A-4I illustrate an example process of fabricating a semiconductor device, according to some aspects of the present disclosure.

FIG. 5 illustrates a flow chart of an example process, according to some aspects of the present disclosure.

Like reference numbers and designations in the various drawings indicate like elements. It is also to be understood that the various exemplary implementations shown in the figures are merely illustrative representations and are not necessarily drawn to scale.

### DETAILED DESCRIPTION

As the demand for high performance and high capacity memory devices is increasing, low cost fabrication processes that can apply high precision self-alignment etching processes are desired. Implementations of the present disclosure provide techniques for managing high bandwidth memory (HBM) with multiple decks, e.g., forming a semiconductor device (such as a memory device) including multiple decks of semiconductor structures stacked along a vertical direction. For example, the semiconductor device can include a first deck of semiconductor structures and a second deck of semiconductor structures, a dielectric layer between the first deck and the second deck, and a first group of contact structures and a second group of contact structures extending along the vertical direction. The first deck is bonded to the second deck by the dielectric layer. The first group of contact structures are coupled to conductive layers of the first deck of semiconductor structures without extending through the dielectric layer. The second group of contact structures extend through the first deck and the dielectric layer and are coupled to conductive layers of the second deck of semiconductor structures.

Implementations of the present disclosure can provide one or more of the following technical advantages and/or benefits. Rather than performing etching to each layer of semiconductor structure, one etching process can be performed on each deck of semiconductor structures, thereby reducing the number of etching and alignment cycles. Thus, the fabrication cost of the semiconductor device can be reduced, and the production yield can be increased. Adjacent semiconductor structures within each deck as well as adjacent decks can be bonded using direct bonding techniques, thereby allowing the semiconductor device to have a large number of semiconductor structures with small pitches. In addition, each semiconductor structure can be thinned, which can reduce a size of the semiconductor device and increase a capacity density of the semiconductor device.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

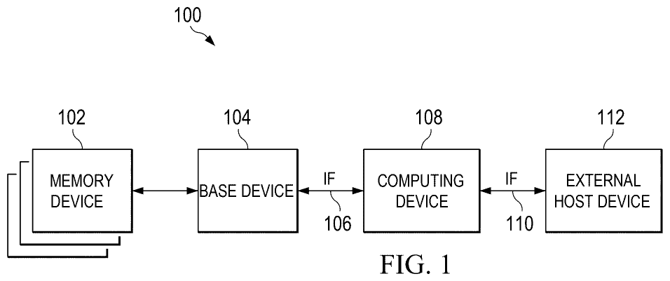

FIG. 1 illustrates a block diagram of an example system 100 having one or more semiconductor devices (e.g., memory devices), according to some aspects of the present disclosure. The system 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1, the system 100 can include one or more memory devices 102, a base device (also referred to as a base die) 104, a computing device 108, and an external host device 112. In some implementations, each of devices 102, 104, 108, and 112 can be a die or multiple dies stacked together. Each of devices 102, 104, 108, and 112 can be manufactured by depositing multiple layers of various materials and etching them onto a semiconductor wafer in intricate patterns defined by a chip design. After the wafer fabrication process is complete, the wafer that includes individual circuits is cut and diced into individual pieces, each of which is a die. Each die can include a fully functional electronic circuit, which can be a microprocessor, memory, sensor, or any other suitable type of integrated circuit. In some embodiments, each die is encapsulated in a protective package, providing physical support, protection from environmental factor, and connections (e.g., through pins or solder balls) to external devices or system.

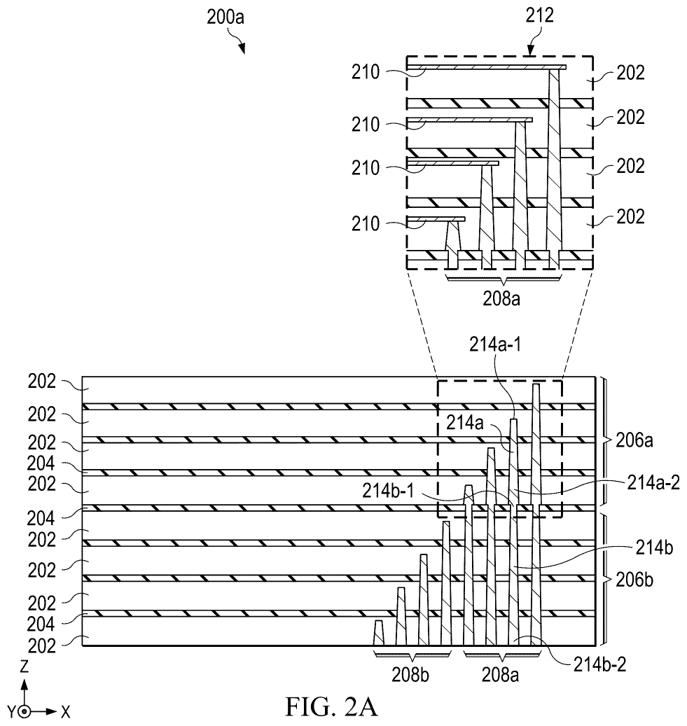

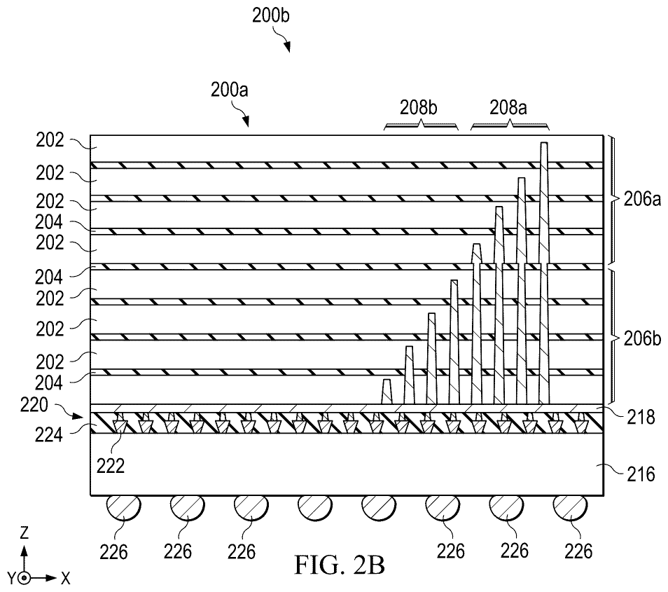

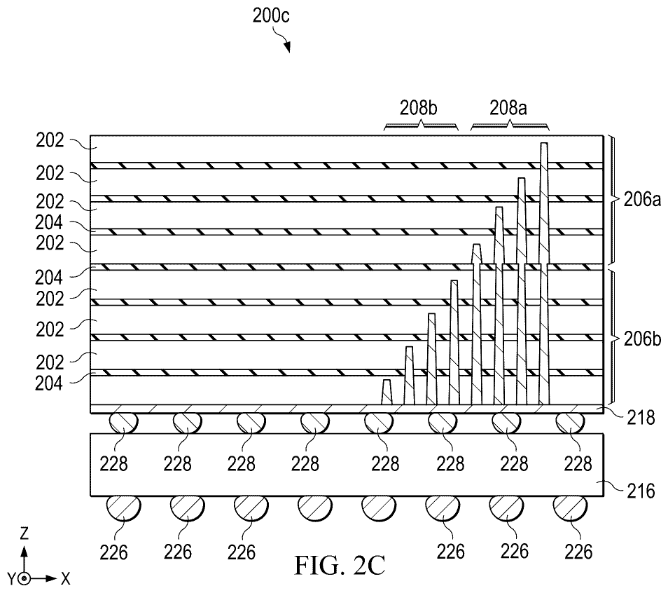

Memory devices 102 can include any memory device disclosed herein, such as a memory device (e.g., a 3D memory device) based on any one of semiconductor devices or semiconductor structures as described with respect to FIGS. 2A-2C, 3A-3B, and 4A-4I. In some implementations, memory devices 102 include one or more dynamic random access memory (DRAM) devices. In some implementations, memory devices 102 include one or more NAND Flash memories. In some implementations, memory devices 102 can include a high bandwidth memory (HBM). In some implementations, memory devices 102 can be stacked together, e.g., as described with further details with respect to FIGS. 2A-2C, 3A-3B, and 4A-4I.

Base device 104 (also referred to as a base device, a logic die, or a buffer die) can include buffer circuitry and test logic for memory devices 102. Base device 104 can be configured to provide physical layer communication protocols (e.g., IEEE-1500) between memory devices 102 and computing device 108. Base device 104 can be configured to transmit data between memory devices 102 and computing device 108 based on control commands and addresses from computing device 108.

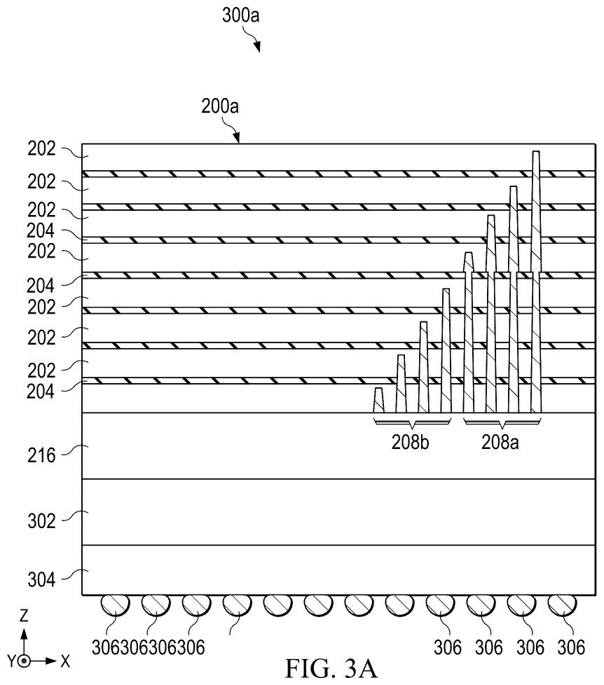

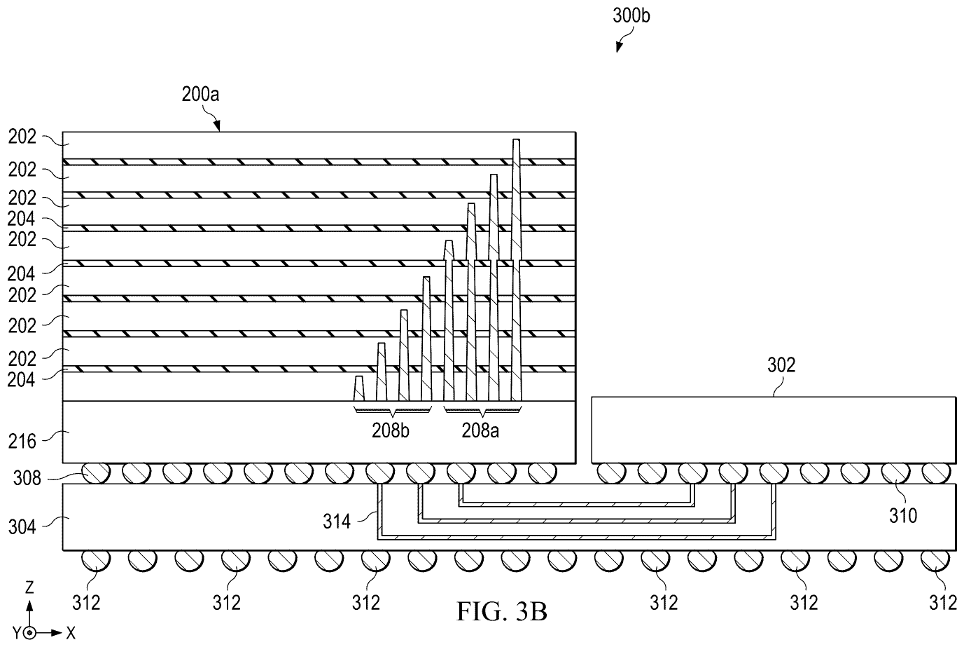

Computing device 108 can be a logic device and can include at least one processor of an electronic device, such as a central processing unit (CPU), a graphics processing unit (GPU), an application-specific integrated circuit (ASIC), or a system-on-chip (SoC), such as an application processor (AP). Computing device 108 can be configured to send or receive data to or from memory devices 102. Computing device 108 is coupled to base device 104 through an interface 106. Interface 106 can include connections provided by bonding contacts (e.g., as described with respect to FIG. 3A) or an interposer (e.g., as described with respect to FIG. 3B). In some implementations, interface 106 includes connections provided by any suitable combination of the aforementioned techniques.

System 100 can further include the external host device 112 coupled to computing device 108 through an interface 110. For example, external host device 112 can be a computer, and computing device 108 can be a CPU of the computer. In this example, interface 110 includes connections provided by a mainboard of the computer that are coupled to the CPU. As another example, external host device 112 is a graphics card, computing device 108 is a GPU of the graphics card, and interface 110 includes connections provided by a printed circuit board (PCB) of the graphics card that are coupled to the GPU.

System 100 may further include a memory controller (a.k.a., a controller circuit, which is not shown in FIG. 1) coupled to memory devices 102. In some implementations, the memory controller is located in the computing device 108. Consistent with implementations of the present disclosure, the memory controller can include conductive interconnections through a cover layer that are in contact with conductive pads in a conductive pad layer, and the memory controller can be coupled to memory devices 102 through at least one of the conductive interconnections. The memory controller is configured to control memory devices 102. For example, the memory controller may be configured to operate channel structures via word lines. The memory controller can manage data stored in memory devices 102 and communicate with computing device 108.

In some implementations, the memory controller is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, the memory controller is designed/configured for operating in a high duty cycle environment SSDs or embedded multi-media-cards (eMMCs) used as data storage for mobile devices, such as smartphones, tablets, laptop computers, etc., and enterprise storage arrays. The memory controller can be configured to control operations of memory devices 102, such as read, erase, and program (or write) operations. The memory controller can also be configured to manage various functions with respect to the data stored or to be stored in memory devices 102 including, but not limited to bad-block management, garbage collection, logical-to-physical address conversion, wear leveling, etc. In some implementations, the memory controller is further configured to process error correction codes (ECCs) with respect to the data read from or written to memory devices 102. In some other implementations, the base device 104 instead of the memory controller is configured to process ECCs. Any other suitable functions may be performed by the memory controller as well, for example, formatting memory devices 102.

The memory controller can communicate with an external device (e.g., computing device 108) according to a particular communication protocol. For example, the memory controller may communicate with the external device through at least one of various interface protocols, such as a USB protocol, an MMC protocol, a peripheral component interconnection (PCI) protocol, a PCIexpress (PCTe or PCI-e) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

The memory controller and one or more memory devices 102 can be integrated into various types of storage devices, for example, be included in the same package, such as a universal Flash storage (UFS) package or an eMMC package. That is, system 100 can be implemented and packaged into different types of end electronic products. For example, the memory controller and a single memory device 102 may be integrated into a memory card. The memory card can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

FIGS. 2A-2C illustrate example semiconductor devices 200a-200c, according to some aspects of the present disclosure.

It is noted that X, Y, and Z axes (also referred to as X, Y, and Z directions) are included in FIGS. 2A-2C to further illustrate the spatial relationship of various components in a semiconductor device. A substrate of the semiconductor device includes two lateral surfaces extending laterally in the X-Y plane: a top surface on the front side of a wafer on which a component of the semiconductor device can be formed, and a bottom surface on the backside opposite to the front side of the wafer. The Z direction is perpendicular to both the X and Y directions. As used herein, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

As shown in FIG. 2A, the semiconductor device 200a includes multiple decks of semiconductor structures 202 stacked (e.g., sequentially) along a vertical direction (e.g., the Z direction). The multiple decks include at least a deck 206a and a deck 206b. Each of the multiple decks includes one or more semiconductor structures 202. Each of the semiconductor structures 202 can be a memory device, such as a dynamic random access memory (DRAM) device. In some implementations, the semiconductor structure 202 can be similar to, or same as the memory device 102 of FIG. 1. For example, each semiconductor structure 202 can include a memory array and a peripheral circuity. The memory array can include an array of memory cells, and the peripheral circuity can be coupled to the memory array and can be configured to control the memory array.

The semiconductor device 200a can include one or more dielectric layers 204 between adjacent semiconductor structures 202. That is, each dielectric layer 204 is sandwiched between two adjacent semiconductor structures 202 and is in contact with the two adjacent semiconductor structures 202. The dielectric layers 204 can extend in the lateral plane (e.g., the X-Y plane) perpendicular to the vertical direction (e.g., the Z direction). Within each deck (e.g., deck 206a or deck 206b), two adjacent semiconductor structures 202 in the deck can be bonded by a dielectric layer 204 therebetween. Two adjacent decks (e.g., deck 206a and deck 206b) can be bonded by a dielectric layer 204 between these two decks.

The semiconductor device 200a can further include contact structures extending along the vertical direction. The contact structures can be divided into multiple groups. Each group of contact structures extend into a corresponding deck and are coupled to a respective semiconductor structure 202 in the corresponding deck. For example, a first group of contact structures 208a extend through the dielectric layer 204 between deck 206a and deck 206b and extend into deck 206a. The first group of contact structures 208a are coupled to conductive layers 210 (as shown in an enlarged view 212 in FIG. 2A) of the semiconductor structures 202 in deck 206a, respectively. A second group of contact structures 208b extend into deck 206b without extending through the dielectric layer 204 between deck 206a and deck 206b. The second group of contact structures 208b are coupled to conductive layers 210 of the semiconductor structures 202 in deck 206b, respectively. In some implementations, the conductive layer 210 in each semiconductor structure 202 of a deck can be configured to provide one or more of power supplies, clock signals, or data path signals to the semiconductor structure 202. For example, the conductive layer 210 can be coupled to one or more of a memory array of the semiconductor structure 202, a peripheral circuit of the semiconductor structure 202, or input/output ports of the semiconductor structure 202.

The conductive layers 210 of the semiconductor structures 202 in the semiconductor device 200a can offset along a horizontal direction (e.g., the X direction) so that a contact structure (e.g., contact structure 208a or 208b) coupled to the conductive layer 210 of a semiconductor structure 202 does not extend through the conductive layer 210 of another semiconductor structure 202. In other words, the conductive layers 210 of the semiconductor structures 202 in the semiconductor device 200a can form a staircase structure. In this way, the fabrication of the contact structures can avoid etching off a material (e.g., metal) of the conductive layer, thereby reducing the fabrication cost and improving the manufacturing efficiency. While the enlarged view 212 illustrates a stepped structure formed by the conductive layers 210, it is understood that in practice any suitable ways to arrange the conductive layers 210 to allow each of the contact structures (e.g., contact structures 208a and 208b) to connect to one conductive layer without extending through other conductive layers can be applied to the semiconductor device 200a.

It is also understood that each of the contact structures (e.g., contact structures 208a and 208b) can connect to one conductive layer of a corresponding semiconductor structure 202 and extend through conductive layers of other semiconductor structures 202. In some implementations, the conductive layers 210 of the semiconductor structures 202 in the semiconductor device 200a can form a structure different from the staircase structure illustrated in the enlarged view 212. For example, the conductive layers 210 can align along the vertical direction (e.g., the Z direction). Spacers for insulation can be formed between the contact structure and the conductive layers that the contact structure is not coupled to.

In some implementations, the contact structure that extends into multiple decks can have multiple segments. Each of the segments is in a corresponding deck that the contact structure extends into. For example, as shown in FIG. 2A, the contact structures 208a extend through the deck 206b and extend into the deck 206a. Each of the contact structures 208a includes two segments 214a and 214b. The segments 214a and 214b are connected. The segment 214b extends through the deck 206b and the dielectric layer 204 between the deck 206a and the deck 206b. The segment 214a extends into the deck 206a and is connected to the conductive layer 210 of a corresponding semiconductor structure 202 in the deck 206a. The segment 214a has an end 214a-1 and 214a-2. The segment 214b has an end 214b-1 and 214b-2. The end 214b-1 and the end 214b-2 are opposite to each other along the vertical direction. The end 214b-2 can be farther away from the segment 214a than the end 214b-1 along the vertical direction. The end 214a-1 of the segment 214a is connected to the conductive layer 210 of the corresponding semiconductor structure 202 in the deck 206a. The end 214a-2 of the segment 214a is connected to the end 214b-1 of the segment 214b. A size of a cross section of the end 214a-2 of the segment 214a is larger than a size of a cross section of the end 214b-lof the segment 214b. The cross section of the end 214a-2 and the cross section of the end 214b-1 can be perpendicular to the Z direction.

In some implementations, the end 214a-2 of the segment 214a is in contact with the dielectric layer 204 between deck 206a and deck 206b along the vertical direction (e.g., the Z direction). In some implementations, the end 214b-1 of the segment 214b is in contact with the dielectric layer 204 between deck 206a and deck 206b along the horizontal direction (e.g., the X direction).

In some implementations, each segment of one of the contact structures 208a and 208b can be in the shape of a cylinder or a pillar. In some implementations, each of the contact structures 208a and 208b has a critical dimension (CD) in a range between 0.5 micrometers (μm) and 10 μm. In some implementations, each of the contact structures 208a and 208b can include an insulating outer layer and a conductive inner layer surrounded by the insulating outer layer. The conductive inner layer can include conductive materials including, but not limited to, tungsten (W), cobalt (Co), copper (Cu), aluminum (Al), silicides, or any combination thereof.

In some implementations, each of the semiconductor structures 202 can have a reduced thickness (along the Z direction) by having their substrates thinned. The thickness of each of the semiconductor structures 202 can be in any suitable range (e.g., between 3 μm and 20 μm).

As shown in FIG. 2B, the semiconductor device 200b includes the semiconductor device 200a and a base device 216. The base device 216 can be similar to, or same as the base device 104 of FIG. 1. The base device 216 and the semiconductor device 200a are stacked along the Z direction. The semiconductor device 200b can further include an interconnect layer 218 and a bonding layer 220. The interconnect layer 218 and the bonding layer 220 are between the semiconductor device 200a and the base device 216 along the Z direction. The interconnect layer 218 is in contact with the semiconductor device 200a and is coupled to the contact structures 208a and 208b. In some implementations, the interconnect layer 218 can be considered as a part of the semiconductor device 200a. For example, the interconnect layer 218 can be considered as a part of the deck 206b. The semiconductor device 200a (which can include the interconnect layer 218) can be bonded to the base device 216 by the bonding layer 220 using hybrid bonding. The hybrid bonding can form bonding between surfaces without using intermediate layers, such as solder or adhesives and can obtain metal-metal bonding and dielectric-dielectric bonding simultaneously. In some implementations, the bonding layer 220 includes conductive bonding contacts 222 and at least one dielectric material 224 isolating the conductive bonding contacts in a horizontal direction (e.g., the X direction). The conductive bonding contacts 222 can include conductive materials including, but not limited to, W, Co, Cu, Al, silicides, or any combination thereof. The at least one dielectric material 224 can include dielectrics including, but not limited to, silicon oxide, silicon nitride, silicon oxynitride, low-k dielectrics, or any combination thereof.

The base device 216 is coupled to the contact structures 208a and the contact structures 208b by the conductive bonding contacts 222 and the interconnect layer 218. The interconnect layer 218 can include interconnects (also referred to herein as “contacts”), including lateral interconnect lines and vertical interconnect access (VIA) contacts. Contact structures 208a and 208b and conductive bonding contacts 222 of the bonding layer 220 can be coupled to the interconnects in the interconnect layer 218. As used herein, the term “interconnects” can broadly include any suitable types of interconnects, such as middle-end-of-line (MEOL) interconnects and back-end-of-line (BEOL) interconnects. The interconnect layer 218 can further include one or more interlayer dielectric (ILD) layers (also known as “intermetal dielectric (IMD) layers”) in which the interconnect lines and the VIA contacts can form. That is, the interconnect layer 218 can include interconnect lines and VIA contacts in multiple ILD layers. The interconnect lines and VIA contacts in the interconnect layer 218 can include conductive materials including, but not limited to, W, Co, Cu, Al, silicides, or any combination thereof. The ILD layers in the interconnect layer 218 can include dielectric materials including, but not limited to, silicon oxide, silicon nitride, silicon oxynitride, low dielectric constant (low-k) dielectrics, or any combination thereof.

The semiconductor device 200b can further include conductive contacts 226 connected to the base device 216. The semiconductor device 200b can be connected to another device (e.g., the computing device 108 of FIG. 1) through the conductive contacts 226. In some implementations, the conductive contacts 226 can be any suitable conductive structures such as micro bumps.

The semiconductor device 200a and the base device 216 can be coupled together using any suitable techniques, which can be different from the example illustrated by FIG. 2B. In some implementations, as shown in FIG. 2C, the semiconductor device 200c includes conductive contacts 228 (e.g., micro bumps) coupled between the semiconductor device 200a and the base device 216. The semiconductor device 200a and the base device 216 are stacked along the vertical direction (e.g., the Z direction). The deck 206b (which can include the interconnect layer 218) of the semiconductor device 200a is coupled and bonded to the base device 216 by the conductive contacts 228. For example, the contact structures 208a and 208b and the conductive contacts 228 can be coupled to the interconnect layer 218. In other words, the base device 216 is coupled to the contact structures 208a and 208b by the interconnect layer 218 and the conductive contacts 228. The semiconductor device 200c can be connected to another device (e.g., the computing device 108 of FIG. 1) through the conductive contacts 226 that are connected to the base device 216 as shown in FIG. 2C.

In some other implementations (not shown), the semiconductor device 200a can be stacked on and bonded to the base device 216 by a bonding layer that is similar to, or same as, one of the dielectric layers 204. For example, the bonding layer can include at least one dielectric material and excludes a conductive bonding contact. The contact structures 208a and 208b can extend through the bonding layer and extend into the base device 216. The contact structures 208a and 208b can be coupled to an interconnect layer in contact with the base device 216. For example, the interconnect layer and the bonding layer can be located at opposite sides of the base device 216. In some implementations, the interconnect layer can be considered as a part of the base device 216. In other words, the base device 216 includes the interconnect layer which is located furthest away from the bonding layer among components in the base device 216 along the vertical direction (e.g., the Z direction). In some implementations, another device (e.g., the computing device 108 of FIG. 1) can be coupled to the semiconductor device 200a through conductive contacts (e.g., micro bumps) connected to the interconnect layer of the base device 216.

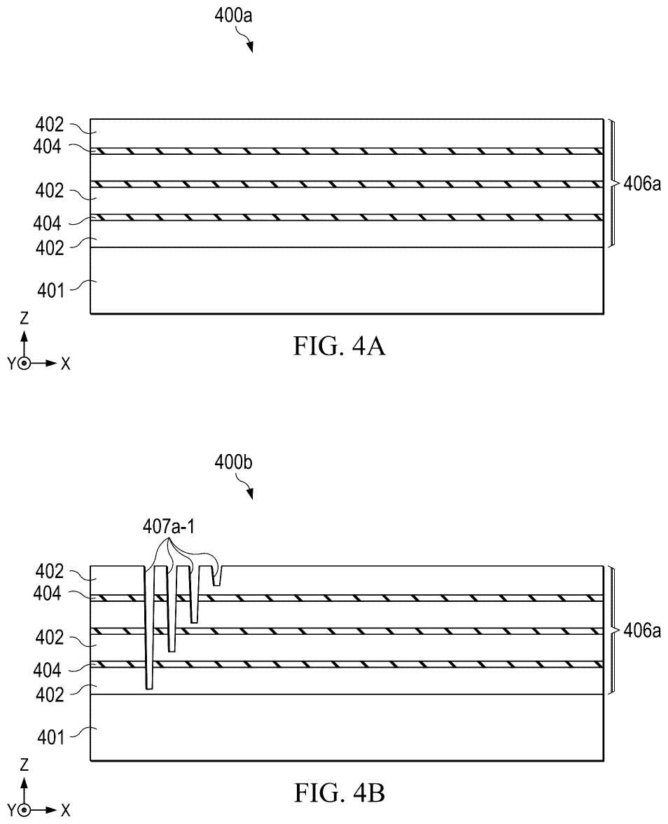

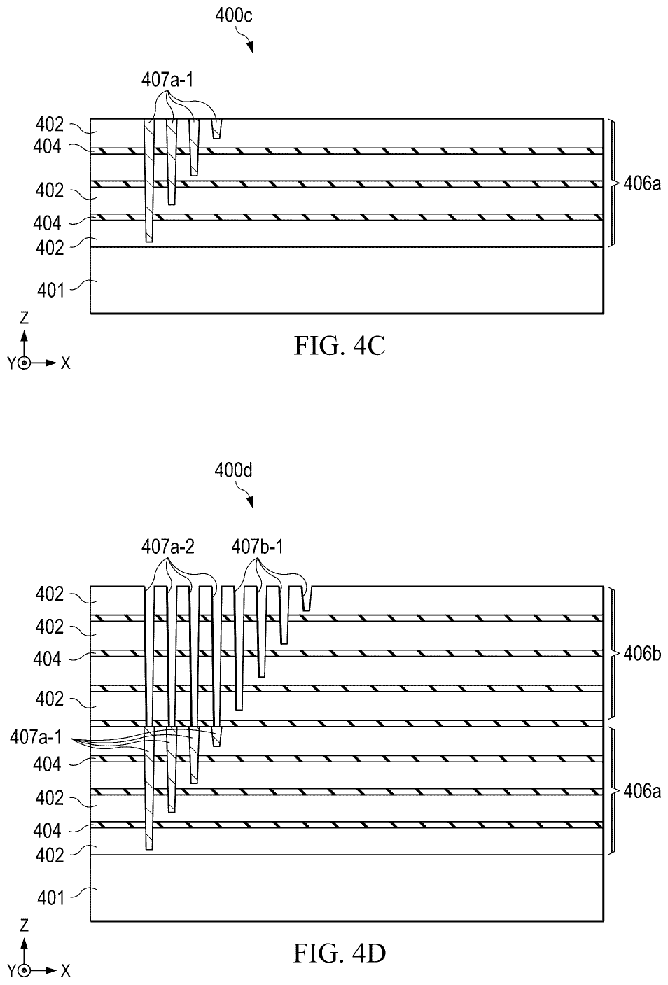

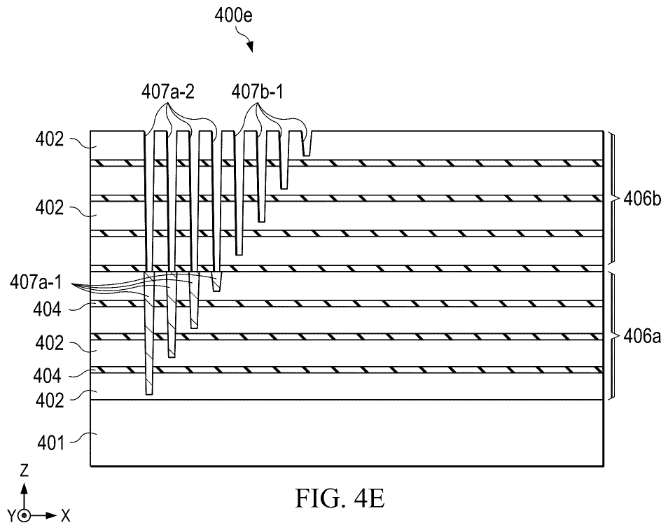

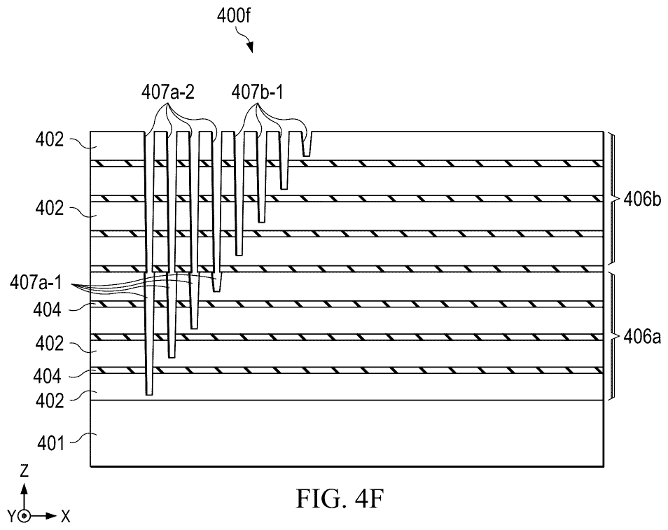

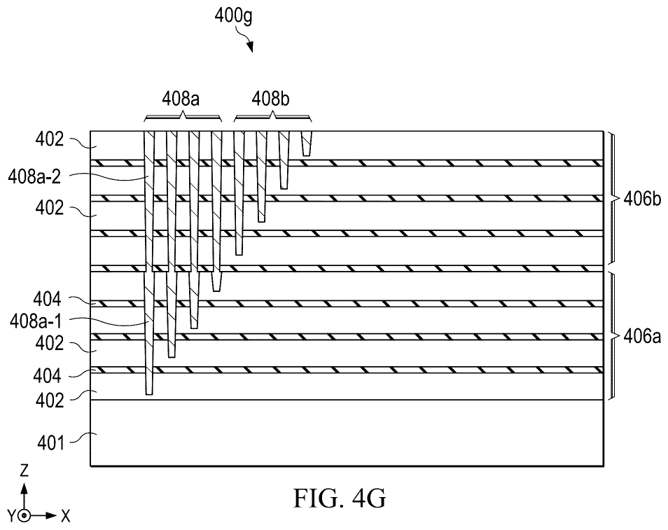

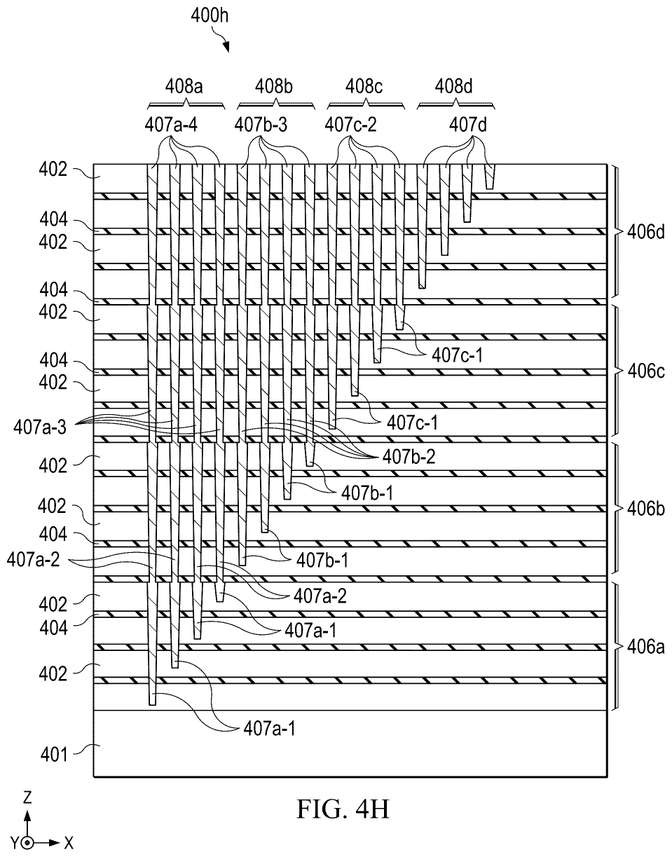

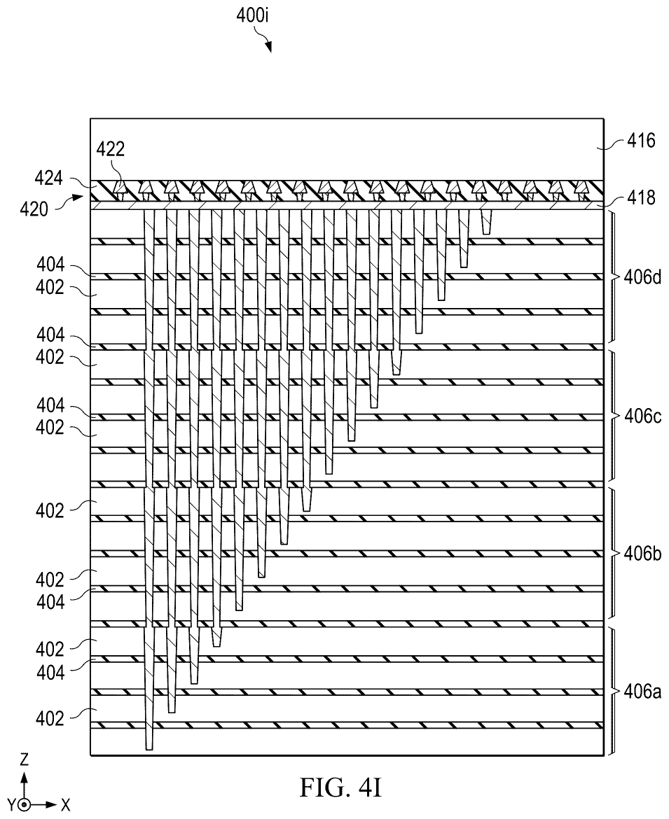

While FIGS. 2A-2C illustrate example semiconductor devices that each include two decks, and each deck includes four semiconductor structures, the technology disclosed herein can be applied to stacking any suitable number of decks (e.g., three, four, or more), and each deck can include any suitable number of semiconductor structures (e.g., one or more). For example, FIG. 4I illustrates another example, where four decks are stacked together. The number of decks and the number of semiconductor structures included in one semiconductor device can be determined based on factors including technology constraints, thermal considerations, signal integrity and interferences, physical size and application, costs and yields, reliability concerns, etc.

FIGS. 3A-3B illustrate example semiconductor devices 300a and 300b that each include the semiconductor device 200a of FIG. 2A and a computing device, according to some aspects of the present disclosure. In some implementations, as shown in FIG. 3A, the semiconductor device 300a includes the semiconductor device 200a, the base device 216, a computing device 302, and an interposer 304 stacked (e.g., sequentially) along the vertical direction (e.g., the Z direction). The computing device 302 (e.g., an SoC) can be similar to, or same as, the computing device 108 of FIG. 1. The interposer 304 can be an example of the interface 110 of FIG. 1. The semiconductor device 200a and the base device 216 in FIG. 3A can be coupled together in any suitable ways, such as those described with reference to FIGS. 2B-2C. The base device 216 can be bonded to the computing device 302 through a bonding layer similar to the bonding layer 220 of FIG. 2B. The computing device 302 can includes VIAs (not shown) extending through the computing device 302 along the Z direction and being coupled to the base device 216. The computing device 302 and the interposer 304 can be bonded through another bonding layer similar to the bonding layer 220 of FIG. 2B. The interposer 304 can include interconnection lines (not shown) that connect the VIAs of the computing device 302 to conductive terminals 306 (e.g., micro bumps). The conductive terminals 306 can be coupled to an external device (e.g., the external host device 112 of FIG. 1).

In some other implementations, as illustrated by the semiconductor device 300b of FIG. 3B, the base device 216 and the computing device 302 are integrated on different positions of the interposer 304 along the X direction. The base device 216 can be coupled to the computing device 302 through the interposer 304. The base device 216 can be connected to conductive terminals 308 on one side of the interposer 304. The computing device 302 can be connected to conductive terminals 310 on the same side of the interposer 304. The semiconductor device 300b can include conductive terminals 312 connected to another side of the interposer 304. Conductive terminals 308, 310, and 312 can be coupled through conductive lines 314 in the interposer 304. The conductive terminals 312 can be coupled to an external device (e.g., the external host device 112 of FIG. 1). In some implementations, the conductive terminals 308, 310, and 312 can be micro bumps.

It is understood that while FIGS. 3A and 3B are for illustration purposes, in practice, the base device 216, the computing device 302, and the interposer 304 can be integrated together using any suitable packaging technology including, for example, Chip-on-Wafer-on-Substrate (CoWoS).

FIGS. 4A-4I illustrate an example process of fabricating a semiconductor device, according to some aspects of the present disclosure. The semiconductor device fabricated in the process can be an example of the semiconductor device 200b as illustrated in FIG. 2B. FIGS. 4A-4I show side views of example semiconductor structures at various stages of the fabrication process.

As shown in FIG. 4A, a semiconductor structure 400a is formed. The semiconductor structure 400a can be formed by stacking a deck 406a of semiconductor structures 402 on a carrier wafer 401 along the vertical direction (e.g., the Z direction). The carrier wafer 401 can serve as a support to the deck 406a. The deck 406a can include one or more semiconductor structures 402. The deck 406a can be similar to, or same as, the deck 206a of FIG. 2A. In some implementations, each of the semiconductor structures 402 in the deck 406a can include at least a semiconductor device or a semiconductor die (e.g., the semiconductor structure 202 of FIG. 2A, which can be a DRAM device) that has a conductive layer (e.g., conductive layer 210 of FIG. 2A). In some implementations, the semiconductor structure 402 can be similar to, or same as the memory device 102 of FIG. 1. For example, each semiconductor structure 402 can include a memory array and a peripheral circuity. The memory array can include an array of memory cells, and the peripheral circuity can be coupled to the memory array and can be configured to control the memory array.

In some implementations, the semiconductor structures 402 of the deck 406a can be stacked on the carrier wafer 401 one by one. For example, the semiconductor structure 402 on the bottom of the deck 406a can be stacked on and bonded to the carrier wafer. Another semiconductor structure 402 can be stacked on and bonded to the semiconductor structure 402 on the bottom of the deck 406a by a dielectric layer 404, and so on. In some other implementations, the deck 406a can be formed first (e.g., in a separate and/or parallel process) and then bonded to the carrier wafer 401. Adjacent semiconductor structures 402 in the deck 406a can be bonded using any suitable bonding technology (e.g., a direct bonding technology). For example, a first dielectric layer (e.g., silicon oxide) can be deposited on the bottom surface of one of the two adjacent semiconductor structures 402 that is on the top, and a second dielectric layer (e.g., silicon oxide) can be deposited on the top surface of another of the two adjacent semiconductor structures 402 that is on the bottom. By applying pressure and heat, the first dielectric layer and the second dielectric layer can be bonded together to form the dielectric layer 404 between the two adjacent semiconductor structures 402.

The deck 406a also can be bonded to the carrier wafer 401 by a bonding process. Any suitable bonding techniques can be applied to the bonding process. For example, the semiconductor structure 402 on the bottom of the deck 406a can be bonded to the carrier wafer 401 through an adhesive layer (not shown) disposed between the deck 406a and the carrier wafer 401. The adhesive layer can include any suitable types of adhesives. In some implementations, the deck 406a also can be bonded to the carrier wafer 401 by a dielectric layer, which can be same as, or similar to, the dielectric layer 404.

As shown in FIG. 4B, a semiconductor structure 400b is formed. The semiconductor structure 400b includes contact holes 407a-1 extending along the vertical direction (e.g., the Z direction) in the deck 406a. The contact holes 407a-1 can be formed in a same etching process (referred to as a first etching process). Each of the contact hole 407a-1 extends into a respective semiconductor structure 402 of the deck 406a and reaches the conductive layer of the semiconductor structure 402 (e.g., conductive layer 210 of FIG. 2A). In some implementations, the semiconductor structures 402 of the deck 406a can have their conductive layers formed in a stepped structure (e.g., similar to the way conductive layer 210 are arranged as shown in FIG. 2A), thereby allowing each of the contact holes 407a-1 to connect to the conductive layer of the corresponding semiconductor structure 402 that the contact hole 407a-1 is connected to and bypass the conductive layers of the other semiconductor structures 402 in the deck 406a.

As shown in FIG. 4C, a semiconductor structure 400c is formed by filling the contact holes 407a-1 in the deck 406a with a sacrificial material (e.g., polysilicon or carbon).

As shown in FIG. 4D, a semiconductor structure 400d is formed by stacking a deck 406b of semiconductor structures 402 on the deck 406a along the vertical direction (e.g., the Z direction). In some implementations, each of the semiconductor structures 402 in the deck 406b can include at least a semiconductor device or a semiconductor die (e.g., the semiconductor structure 202 of FIG. 2A, which can be a DRAM device) that has a conductive layer (e.g., conductive layer 210 of FIG. 2A). In some implementations, adjacent semiconductor structures 402 in the deck 406b can be bonded by a dielectric layer 404 therebetween (e.g., using the direct bonding technology described with reference to FIG. 4A). The deck 406b can be bonded to the deck 406a by a dielectric layer 404 therebetween in a similar way.

As shown in FIG. 4E, a semiconductor structure 400e is formed by forming contact holes 407a-2 and contact holes 407b-1 in the deck 406b. The contact holes 407a-2 and the contact holes 407b-1 can be formed by a same etching process (referred to as a second etching process). The contact holes 407a-2 and the contact holes 407b-1 extend along the vertical direction (e.g., the Z direction). Each of the contact holes 407a-2 extends through the deck 406b and the dielectric layer 404 between the deck 406b and the deck 406a and is connected to a respective contact hole of the contact holes 407a-1 in the deck 406a. In other words, the contact hole 407a-2 can expose the sacrificial material in the corresponding contact hole 407a-1 in the deck 406a.

Each of the contact holes 407b-1 extends into a respective semiconductor structure 402 of the deck 406b and reaches the conductive layer of the semiconductor structure 402 (e.g., conductive layer 210 of FIG. 2A). In some implementations, the semiconductor structures 402 of the deck 406b can have their conductive layers formed in a stepped structure (e.g., similar to the way conductive layer 210 are arranged as shown in FIG. 2A), thereby allowing each of the contact holes 407b-1 to connect to the conductive layer of the corresponding semiconductor structure 402 that the contact hole 407b-1 is connected to and bypass the conductive layers of the other semiconductor structures 402 in the deck 406b.

As shown in FIG. 4F, a semiconductor structure 400f is formed by removing the sacrificial material in the contact holes 407a-1 in the deck 406a. In this way, each of the contact holes 407a-2 is connected to one of the contact holes 407a-1.

As shown in FIG. 4G, a semiconductor structure 400g is formed. The semiconductor structure 400g includes contact structures 408a in the contact holes 407a-1 and the contact holes 407a-2 and contact structures 408b in the contact holes 407b-1. The contact structures 408a extend through the dielectric layer 404 between the deck 406a and the deck 406b and extend into the deck 406a along the vertical direction (e.g., the Z direction). The contact structures 408a are coupled to the conductive layers of the semiconductor structures 402 in deck 406a, respectively. The contact structures 408b extend into the deck 406b along the vertical direction (e.g., the Z direction) without extending through the dielectric layer 404 between the deck 406a and the deck 406b. The contact structures 408b are coupled to the conductive layers of the semiconductor structures 402 in the deck 406b, respectively. In some implementations, the contact structures 408a can be formed by depositing at least one conductive material into the contact holes 407a-1 and 407a-2, and the contact structures 408b can be formed by depositing at least one conductive material into the contact holes 407b-1. In some implementations, each of the contact structures 408a and 408b can include an insulating outer layer and a conductive inner layer surrounded by the insulating outer layer. The insulating outer layer can be formed, for example, by depositing an insulating material (e.g., a dielectric material such as silicon oxide) on an inner surface of a corresponding contact hole. The conductive inner layer can be formed, for example, by depositing a conductive material (e.g., W, Co, Cu, Al, silicides, or any combination thereof) into a space formed in the insulating outer layer. As shown in FIG. 4G, each of the contact structures 408a can include a segment 408a-1 formed in the deck 406a and a segment 408a-2 formed in the deck 406b.

As shown in FIG. 4H, a semiconductor structure 400h is formed. The semiconductor structure 400h includes a deck 406c of semiconductor structures 402 and a deck 406d of semiconductor structures 402. Similar to the procedure described with reference to FIG. 4A, the deck 406c can be stacked on and bonded to the deck 406b. Contact holes 407a-3, 407b-2, and 407c-1 can be formed in the deck 406c in a same etching process (referred to as a third etching process). The contact holes 407a-3 can be connected to the contact holes 407a-2. The contact holes 407b-2 can be connected to the contact holes 407b-1. Each of the contact holes 407c-1 extends into a respective semiconductor structure 402 of the deck 406c and reaches a conductive layer of the semiconductor structure 402 (e.g., conductive layer 210 of FIG. 2A). The contact holes 407a-3, 407b-2, and 407c-1 can be filled by the sacrificial material.

Then the deck 406d can be stacked on and bonded to the deck 406c. Contact holes 407a-4, 407b-3, 407c-2, and 407d can be formed in the deck 406d in a same etching process (referred to as a fourth etching process). The contact holes 407a-4 can be connected to the contact holes 407a-3. The contact holes 407b-3 can be connected to the contact holes 407b-2. The contact holes 407c-2 can be connected to the contact holes 407c-1. Each of the contact holes 407d extends into a respective semiconductor structure 402 of the deck 406d and reaches a conductive layer of the semiconductor structure 402 (e.g., conductive layer 210 of FIG. 2A).

Contact structures 408a, 408b, 408c, and 408d in the semiconductor structure 400h can be formed by removing the sacrificial material in the contact holes 407a-3, 407b-2, and 407c-1 and depositing at least one conductive material into the contact holes 407a-4, 407a-3, 407b-3, 407b-2, 407c-2, 407c-1, and 407d (e.g., similar to the deposition procedure described with respect to FIG. 4G).

In some implementations, the contact structures 408a, 408b, 408c, and 408d in the semiconductor structure 400h can be formed by applying variations to the operations described with respect to FIGS. 4F-4H. For example, in stead of removing the sacrificial material in the contact holes 407a-1 as described with respect to FIG. 4E, the contact holes 407a-2 and 407b-1 can be filled with the sacrificial material. After stacking the deck 406c on the deck 406b and forming the contact holes 407a-3, 407b-2, and 407c-1 in the deck 406c, the contact holes 407a-3, 407b-2, and 407c-1 also can be filled with the sacrificial material. After forming the contact holes 407a-4, 407b-3, 407c-2, and 407d in the deck 406d, the sacrificial material in the contact holes 407a-3, 407a-2, 407a-1, 407b-2, 407b-1, and 407c-1 can be removed. Then the contact structures 408a, 408b, 408c, and 408d in the semiconductor structure 400h can be formed by depositing at least one conductive material into the contact holes 407a-4, 407a-3, 407a-2, 407a-1, 407b-3, 407b-2, 407b-1, 407c-2, 407c-1, and 407d.

The semiconductor structures 402 and the carrier wafer 401 can have any suitable thicknesses along the Z direction. In some implementations, each of the semiconductor structures 402 can be thinned. Thinning the semiconductor structure 402 includes removing a top portion (e.g., a portion farthest from the carrier wafer 401 along the Z direction) of the semiconductor structure 402. For example, the thickness of semiconductor structure 402 can be reduced from about 40-50 μm to 3-20 μm by thinning. In some implementations, semiconductor structure 402 includes a substrate on its bottom and is flipped upside down. That is, the substrate of the semiconductor structure 402 becomes the top of the semiconductor structure 402 after the flip. Thus, a portion of the substrate of the semiconductor structure 402 is removed by thinning the top portion of the semiconductor structure 402. In some implementations, after being thinned, the semiconductor structure 402 can still maintain its shape without producing substantial distortion or deformation due to the support provided by the carrier wafer 401.

As shown in FIG. 4I, a semiconductor structure 400i is formed. The carrier wafer 401 can be removed by a debonding process. The semiconductor structure 400i further includes an interconnect layer 418, a bonding layer 420, and a base device 416. The interconnect layer 418 can be formed on top of the deck 406d. The interconnect layer 418 can be an example of the interconnect layer 218 of FIG. 2B. In some implementations, the interconnect layer 418 can be considered as a part of the deck 406d. The contact structures 408a, 408b, 408c, and 408d can be coupled to interconnects of the interconnect layer 418. The base device 416 can be stacked on the deck 406d along the vertical direction (e.g., the Z direction). The base device 416 can be an example of the base device 216 of FIG. 2B. The base device 416 can be bonded to the deck 406d by the bonding layer 420 using hybrid bonding. The hybrid bonding can form bonding between surfaces without using intermediate layers, such as solder or adhesives and can obtain metal-metal bonding and dielectric-dielectric bonding simultaneously. In some implementations, the bonding layer 420 includes conductive bonding contacts 422 and at least one dielectric material 424 isolating the conductive bonding contacts in a horizontal direction (e.g., the X direction). The conductive bonding contacts 422 can include conductive materials including, but not limited to, W, Co, Cu, Al, silicides, or any combination thereof. The at least one dielectric material 424 can include dielectrics including, but not limited to, silicon oxide, silicon nitride, silicon oxynitride, low-k dielectrics, or any combination thereof.

In some implementations, the bonding layer 420 can be formed as follows. A first bonding layer can be formed on a top surface of the interconnect layer 418. The first bonding layer can include conductive bonding contacts coupled to the interconnects of the interconnect layer 418 and a dielectric material isolating the conductive bonding contacts of the first bonding layer. A second bonding layer can be formed on a bottom surface of the base device 416. The second bonding layer can include conductive bonding contacts coupled to the base device 416 and a dielectric material isolating the conductive bonding contacts of the second bonding layer. By applying pressure and heat, the bonding layer 420 can be formed by bonding the conductive bonding contacts of the first bonding layer to the conductive bonding contacts of the second bonding layer and bonding the dielectric material of the first bonding layer to the dielectric material of the second bonding layer.

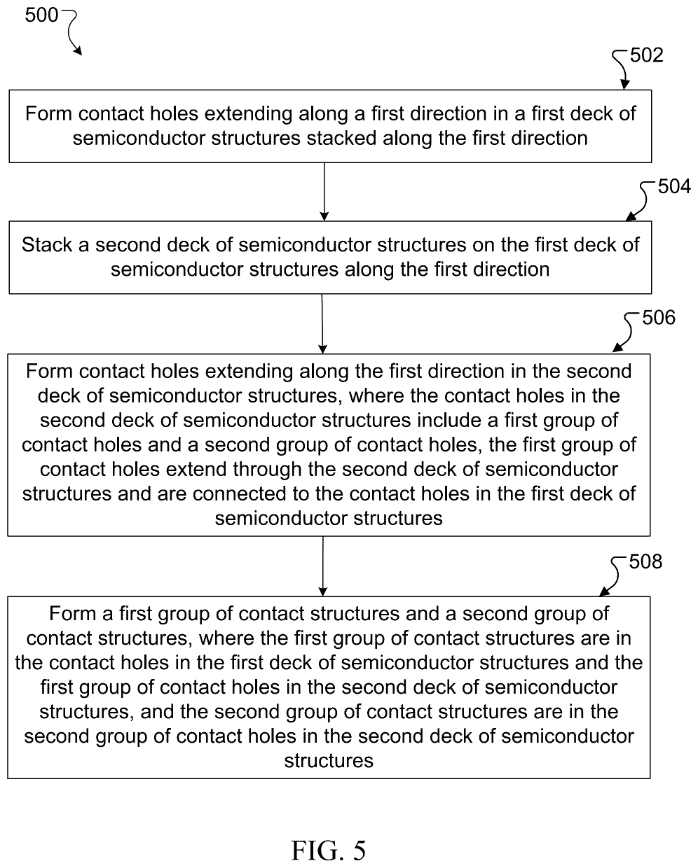

FIG. 5 illustrates a flow chart of an example process 500, according to some aspects of the present disclosure. The process 500 can be performed to form a semiconductor device. For example, the semiconductor device can be similar to, or same as, the semiconductor device 200a of FIG. 2A, the semiconductor device 200b of FIG. 2B, the semiconductor device 200c of FIG. 2C, or the semiconductor structure 400i of FIG. 4I. The process 500 can be described in view of FIGS. 4A-4I. The process 500 can include one or more steps of the fabrication process of forming the semiconductor structures in FIGS. 4A-4I. It is understood that the operations shown in process 500 are not exhaustive and that other operations can be performed as well before, after, or between any of the illustrated operations. Further, some of the operations may be performed simultaneously, or in a different order than shown in FIG. 5.

At operation 502, contact holes (e.g., contact holes 407a-1 of FIG. 4B) extending along a first direction (e.g., the Z direction) in a first deck (e.g., deck 406a of FIG. 4A and FIG. 4B) of semiconductor structures (e.g., semiconductor structures 402 of FIG. 4A and FIG. 4B) stacked along the first direction are formed. In some implementations, the contact holes in the first deck of semiconductor structures are formed by a first etching process. In some implementations, the contact holes in the first deck of semiconductor structures include at least a first contact hole extending to a conductive layer of a corresponding semiconductor structure in the first deck of semiconductor structures (e.g., as described with reference to FIG. 4B). In some implementations, the process 500 further includes filling the contact holes in the first deck of semiconductor structures with a sacrificial material (e.g., as described with reference to FIG. 4C).

At operation 504, a second deck (e.g., deck 406b of FIG. 4D) of semiconductor structures are stacked on the first deck of semiconductor structures along the first direction. In some implementation, the second deck of semiconductor structures can be bonded to the first deck of semiconductor structures by a dielectric layer (e.g., the dielectric layer 404 between deck 406a and deck 406b of FIG. 4D).

At operation 506, contact holes extending along the first direction in the second deck of semiconductor structures are formed. The contact holes in the second deck of semiconductor structures include a first group of contact holes (e.g., contact holes 407a-2 of FIG. 4E) and a second group of contact holes (e.g., contact holes 407b-1 of FIG. 4E). The first group of contact holes extend through the second deck of semiconductor structures and are connected to the contact holes (e.g., contact holes 407a-1) in the first deck of semiconductor structures. In some implementations, the contact holes in the second deck of semiconductor structures are formed by a second etching process (e.g., as described with reference to FIG. 4E). In some implementations, the first group of contact holes in the second deck of semiconductor structures extend through the dielectric layer (e.g., the dielectric layer 404 between deck 406a and deck 406b of FIG. 4E) and extend to the sacrificial material in the contact holes in the first deck of semiconductor structures. In some implementations, the second group of contact holes in the second deck of semiconductor structures include at least a second contact hole extending to a conductive layer of a corresponding semiconductor structure in the second deck of semiconductor structures (e.g., as described with reference to FIG. 4E). In some implementations, the process 500 further includes removing the sacrificial material in the contact holes in the first deck of semiconductor structures to connect the contact holes in the first deck of semiconductor structures with the first group of contact holes in the second deck of semiconductor structures (e.g., as described with reference to FIG. 4F).

At operation 508, a first group of contact structures (e.g., contact structures 408a of FIG. 4G) and a second group of contact structures (e.g., contact structures 408b of FIG. 4G) are formed. The first group of contact structures are in the contact holes (e.g., contact holes 407a-1 of FIG. 4G) in the first deck of semiconductor structures and the first group of contact holes (e.g., contact holes 407a-2 of FIG. 4G) in the second deck of semiconductor structures. The second group of contact structures are in the second group of contact holes (e.g., contact holes 407b-1) in the second deck of semiconductor structures. In some implementations, the first group of contact structures are formed by depositing at least one conductive material into the contact holes in the first deck of semiconductor structures and the first group of contact holes in the second deck of semiconductor structures (e.g., as described with reference to FIG. 4G). In some implementations, the second group of contact structures are formed by depositing at least one conductive material into the second group of contact holes in the second deck of semiconductor structures (e.g., as described with reference to FIG. 4G).

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−0.10%, .+−0.20%, or .+−0.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
multiple decks of semiconductor structures stacked along a first direction, wherein the multiple decks of semiconductor structures comprise at least a first deck of semiconductor structures and a second deck of semiconductor structures;
multiple dielectric layers between the multiple decks of semiconductor structures, wherein the multiple dielectric layers extend along a second direction perpendicular to the first direction and comprise at least a first dielectric layer between the first deck of semiconductor structures and the second deck of semiconductor structures, and the first deck of semiconductor structures is bonded to the second deck of semiconductor structures by the first dielectric layer; and
multiple groups of contact structures extending along the first direction, wherein the multiple groups of contact structures comprise at least a first group of contact structures and a second group of contact structures, the first group of contact structures are coupled to conductive layers of the first deck of semiconductor structures without extending through the first dielectric layer, the second group of contact structures extend through the first deck of semiconductor structures and the first dielectric layer and are coupled to conductive layers of the second deck of semiconductor structures.

2. The semiconductor device according to claim 1, wherein:
the multiple decks of semiconductor structures further comprise a third deck of semiconductor structures;
the multiple dielectric layers further comprise a second dielectric layer between the second deck of semiconductor structures and the third deck of semiconductor structures; and
the multiple groups of contact structures further comprise a third group of contact structures, wherein the third group of contact structures extend through the first deck of semiconductor structures, the first dielectric layer, the second deck of semiconductor structures, and the second dielectric layer and are coupled to conductive layers of the third deck of semiconductor structures.

3. The semiconductor device according to claim 1, further comprising a base die, wherein:
the multiple decks of semiconductor structures and the base die are stacked along the first direction; and
the base die is coupled to the first group of contact structures and the second group of contact structures.

4. The semiconductor device according to claim 3, wherein:
the first deck of semiconductor structures is bonded to the base die by a bonding layer between the first deck of semiconductor structures and the base die;
the first deck of semiconductor structures comprises an interconnect layer in contact with the bonding layer;
the bonding layer comprises conductive bonding contacts and at least one dielectric material isolating the conductive bonding contacts in the second direction; and
the base die is coupled to the first group of contact structures and the second group of contact structures by the interconnect layer and the conductive bonding contacts.

5. The semiconductor device according to claim 3, wherein:
the first deck of semiconductor structures is bonded to the base die by conductive micro bumps between the first deck of semiconductor structures and the base die;
the first deck of semiconductor structures comprises an interconnect layer in contact with the conductive micro bumps; and
the base die is coupled to the first group of contact structures and the second group of contact structures by the interconnect layer and the conductive micro bumps.

6. The semiconductor device according to claim 3, wherein:
the first deck of semiconductor structures is bonded to the base die by a bonding layer between the first deck of semiconductor structures and the base die;
the bonding layer comprises at least one dielectric material and excludes a conductive bonding contact;
the first group of contact structures and the second group of contact structures extend through the bonding layer and extend into the base die;
the base die comprises an interconnect layer furthest away from the bonding layer among components in the base die along the first direction; and
the interconnect layer is coupled to the first group of contact structures and the second group of contact structures.

7. The semiconductor device according to claim 1, wherein:
the multiple dielectric layers further comprise a first group of dielectric layers between the first deck of semiconductor structures and a second group of dielectric layers between the second deck of semiconductor structures;
two adjacent semiconductor structures of the first deck of semiconductor structures are bonded by one of the first group of dielectric layers; and
two adjacent semiconductor structures of the second deck of semiconductor structures are bonded by one of the second group of dielectric layers.

8. The semiconductor device according to claim 1, wherein at least one semiconductor structure of the multiple decks of semiconductor structures is a dynamic random-access memory (DRAM) device.

9. A semiconductor device, comprising:
multiple decks of semiconductor structures stacked along a first direction, wherein the multiple decks of semiconductor structures comprise at least a first deck of semiconductor structures and a second deck of semiconductor structures bonded by a first dielectric layer between the first deck of semiconductor structures and the second deck of semiconductor structures;
a first group of contact structures extending along the first direction and being connected to the first deck of semiconductor structures; and
a second group of contact structures extending along the first direction and being connected to the second deck of semiconductor structures, wherein the second group of contact structures comprise at least a first contact structure, the first contact structure comprises a first segment and a second segment, the first segment extends through the first deck of semiconductor structures and the first dielectric layer, and the second segment is connected to one of the second deck of semiconductor structures.

10. The semiconductor device according to claim 9, wherein:
the first segment comprises a first end and a second end;
the second segment comprises a first end and a second end;
the first end of the second segment is connected to the second end of the first segment;
the first end of the first segment is farther away from the second segment than the second end of the first segment along the first direction;
the second end of the second segment is connected to the one of the second deck of semiconductor structures; and
a size of a cross section of the first end of the second segment is larger than a size of a cross section of the second end of the first segment.

11. The semiconductor device according to claim 10, wherein:
the first end of the second segment is in contact with the first dielectric layer along the first direction; and
the second end of the first segment is in contact with the first dielectric layer along a second direction perpendicular to the first direction.

12. The semiconductor device according to claim 9, wherein each of the first group of contact structures and the second group of contact structures has a critical dimension (CD) in a range between 0.5 micrometers (μm) and 10 μm.

13. The semiconductor device according to claim 9, wherein each of the first group of contact structures and the second group of contact structures comprises an insulating outer layer and a conductive inner layer surrounded by the insulating outer layer.

14. The semiconductor device according to claim 9, wherein at least one semiconductor structure of the multiple decks of semiconductor structures is a dynamic random-access memory (DRAM) device.

15. A method, comprising:
forming contact holes extending along a first direction in a first deck of semiconductor structures stacked along the first direction;
stacking a second deck of semiconductor structures on the first deck of semiconductor structures along the first direction;
forming contact holes extending along the first direction in the second deck of semiconductor structures, wherein the contact holes in the second deck of semiconductor structures comprise a first group of contact holes and a second group of contact holes, the first group of contact holes extend through the second deck of semiconductor structures and are connected to the contact holes in the first deck of semiconductor structures; and
forming a first group of contact structures and a second group of contact structures, wherein the first group of contact structures are in the contact holes in the first deck of semiconductor structures and the first group of contact holes in the second deck of semiconductor structures, and the second group of contact structures are in the second group of contact holes in the second deck of semiconductor structures.

16. The method of claim 15, wherein:
the contact holes in the first deck of semiconductor structures are formed by a first etching process; and
the contact holes in the first deck of semiconductor structures comprise at least a first contact hole extending to a conductive layer of a corresponding semiconductor structure in the first deck of semiconductor structures.

17. The method of claim 15, further comprising:
filling the contact holes in the first deck of semiconductor structures with a sacrificial material; and
bonding the second deck of semiconductor structures to the first deck of semiconductor structures by a dielectric layer.

18. The method of claim 17, wherein:
the contact holes in the second deck of semiconductor structures are formed by a second etching process;
the first group of contact holes in the second deck of semiconductor structures extend through the dielectric layer and extend to the sacrificial material in the contact holes in the first deck of semiconductor structures; and
the second group of contact holes in the second deck of semiconductor structures comprise at least a second contact hole extending to a conductive layer of a corresponding semiconductor structure in the second deck of semiconductor structures.

19. The method of claim 17, further comprising:
removing the sacrificial material in the contact holes in the first deck of semiconductor structures to connect the contact holes in the first deck of semiconductor structures with the first group of contact holes in the second deck of semiconductor structures.

20. The method of claim 17, wherein:
the first group of contact structures are formed by depositing at least one conductive material into the contact holes in the first deck of semiconductor structures and the first group of contact holes in the second deck of semiconductor structures; and
the second group of contact structures are formed by depositing at least one conductive material into the second group of contact holes in the second deck of semiconductor structures.
